(19) United States
(12) Patent Application Publication
(10) Pub. No.: US 2003/0102087 A1
(43) Pub. Date: Jun. 5, 2003

(54) Plasma processing apparatus and processing method

(76) Inventors: Youbun Ito, Nirasaki-shi (JP); Takayuki Katsunuma, Nirasaki-shi (JP); Koichiro Inazawa, Nirasaki-shi (JP); Tomoki Suemasa, Santo Clara, CA (US); Jun Hirose, Nirasaki-shi (JP); Hiroo Ono, Nirasaki-shi (JP); Kazuya Nagaseki, Nirasaki-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 10/305,951

(22) Filed: Nov. 29, 2002

Related U.S. Application Data
(63) Continuation of application No. PCT/JP01/04448, filed on May 28, 2001.

(30) Foreign Application Priority Data
May 29, 2000 (JP) 2000-158448

(51) Int. Cl. C23F 1/00; C23C 16/00

(52) U.S. Cl. 156/345.46; 118/723 E

(57) ABSTRACT

In a plasma processing apparatus of this invention, a ring-like segment magnet is formed around an upper portion of a chamber so a magnetic field is generated around a processing space. The segment magnet can be rotated by a rotating mechanism in the circumferential direction of the chamber. A magnetic field is generated around the processing space by a magnetic field generating means. That position where a substrate to be processed is present is set in a substantial non-magnetic field state, so charge-up damage is prevented. Due to the plasma confining effect of this magnetic field, the plasma processing rate of the substrate to be processed is set to be almost equal between the edge and center of the substrate to be processed, thereby making the processing rate uniform. A pivoting means is provided so as to alter the gap between the magnets or directions of magnetization thereof.

### CROSS-REFERENCE TO RELATED APPLICATIONS

This is a Continuation Application of PCT Application No. PCT/JP01/04448, filed May 28, 2001, which was not published under PCT Article 21(2) in English.

This application is based upon and claims the benefit of priority from the prior Japanese Patent Application No. 2000-158448, filed May 29, 2000, the entire contents of which are incorporated herein by reference.

### BACKGROUND OF THE INVENTION

1. Field of the Invention

The present invention relates to a plasma processing apparatus and processing method for processing a substrate to be processed such as a semiconductor wafer with a plasma.

2. Description of the Related Art

In recent years, a magnetron plasma etching apparatus for performing micropattern etching by generating a high-density plasma in a comparatively low-pressure atmosphere has been put into practical use. In this apparatus, a permanent magnet is arranged above a chamber. A magnetic field emanating from the permanent magnet is applied horizontally to a semiconductor wafer (to be merely referred to as a wafer hereinafter). Simultaneously, a high-frequency electric field perpendicular to the magnetic field is applied to the wafer. The drift motion of electrons caused upon application of the magnetic and electric fields is utilized to etch the wafer with a very high efficiency.

In the magnetron plasma, what contributes to the drift motion of electrons is a magnetic field perpendicular to the electric field, i.e., a magnetic field horizontal to the semiconductor wafer. As a uniform horizontal magnetic field is not always formed with the above apparatus, the plasma uniformity is not sufficient. Thus, a nonuniform etching rate, charge-up damage, and the like may occur.

In order to avoid these problems, formation of a horizontal magnetic field uniform with respect to a wafer in a processing space in a chamber is sought for. As a magnet that can generate such a magnetic field, a dipole ring magnet is known.

As shown in FIG. 7, this dipole ring magnet 102 is formed by arranging a plurality of anisotropic segment columnar magnets 103 in a ring-like shape outside a chamber 101. The directions of magnetization of the plurality of anisotropic segment columnar magnets 103 are slightly shifted from each other to form a uniform horizontal magnetic field B as a whole.

FIG. 7 is a view (plan view) of the apparatus seen from above. The proximal end side of the direction of the magnetic field is indicated by N, the distal end side thereof is indicated by S, and positions at 90° from N and S are respectively indicated by E and W. Reference numeral 100 denotes a wafer.

In this dipole ring magnet, the uniformity of the magnetic field is considerably improved when compared to that of a conventional magnetic field generating apparatus. However, the horizontal magnetic field formed by the dipole ring magnet is a horizontal magnetic field directed in only one direction from N to S. Accordingly, electrons will perform drift motion to travel in one direction, causing nonuniformity in the plasma density. More specifically, assume that the electrons travel in the direction of the outer product (vector) of the electric field and the magnetic field. In other words, assume that the electric field is formed to extend downward from above. In this case, the electrons travel from E to W while performing drift motion. Consequently, the plasma density is low on the E side and high on the W side, resulting in nonuniformity. If the plasma density becomes nonuniform in this manner, charge-up damage may occur when a hole is formed by etching.

In this manner, with the conventional magnetron plasma etching apparatus, charge-up damage inevitably occurs. In order to eliminate the charge-up damage completely, the magnet must be removed.

When the magnet is removed, the charge-up damage may be eliminated. Sometimes, however, the etching range within the wafer surface increases at its center where RF power is supplied. This phenomenon may not become a major issue when the frequency of the RF power to be supplied is low. When the magnet is removed, the plasma density may be decreased. In order to compensate for this decrease, the frequency of the RF power may be increased, so a recently required highly efficient etching process with a high plasma density is realized. The above phenomenon becomes conspicuous in this case.

### BRIEF SUMMARY OF THE INVENTION

It is an object of the present invention to provide a plasma processing apparatus and processing method that can make the processing rate uniform without causing charge-up damage when a substrate to be processed has plasma processing applied to it.

In order to achieve the above object, the present invention provides a plasma processing apparatus comprising

a chamber capable of maintaining a vacuum state,

first and second electrodes formed in the chamber to oppose each other,

RF power applying means for applying a RF power to the second electrode to generate an electric field between the first and second electrodes,

process gas supply means for supplying a process gas into the chamber,

magnetic field generating means, provided around the chamber, for generating, at the periphery of a processing space formed between the first and second electrodes, a magnetic field stronger than a magnetic field at the center of the processing space, and

rotating means for rotating the magnetic field generating means in a circumferential direction of the chamber,

wherein while a magnetic field is generated around the processing space by the magnetic field generating means, a plasma of the process gas is generated by a high-frequency electric field generated between the first and second electrodes so a substrate to be processed has plasma processing applied to it.

The present invention provides a plasma processing apparatus comprising a cylindrical chamber capable of holding a vacuum state, first and second electrodes formed in the chamber to oppose each other, RF wave applying means for applying an RF wave to the second electrode to generate an electric field between the first and second electrodes, process gas supply means for supplying a process gas into the chamber, magnetic field generating means, provided around the chamber, for generating a magnetic field around a processing space formed between the first and second electrodes, and rotating means for rotating the magnetic field generating means in a circumferential direction of the chamber to uniformly apply the strength of the magnetic field to a substrate to be processed over time, wherein while the substrate to be processed is held on the second electrode and a magnetic field is generated around the processing space by the rotating magnetic field generating means, a plasma of the process gas is generated by an RF electric field generated between the first and second electrodes so the substrate to be processed has plasma processing applied to it.

The present invention provides a plasma processing apparatus comprising a chamber capable of holding a vacuum state, a pair of electrodes formed in the chamber to oppose each other, electric field generating means for generating an RF electric field between the pair of electrodes, process gas supply means for supplying a process gas into the chamber, and magnetic field generating means, annularly provided around the chamber and having first and second ring magnets in a multi-pole state each formed by arranging around the chamber in a ring-like shape a plurality of segment magnets comprised of permanent magnets arranged in opposite directions between the electrodes, the magnets being arranged with arbitrary gaps therebetween, for generating a magnetic field in a processing space formed between the pair of electrodes, wherein while a substrate to be processed is supported by one of the electrodes and a magnetic field is generated around the processing space by the magnetic field generating means, a plasma of the process gas is generated by an RF electric field generated between the pair of electrodes so the substrate to be processed has plasma processing applied to it.

The present invention provides a plasma processing method characterized in that a pair of electrodes are arranged in a chamber, a substrate to be processed is supported by either one of the electrodes, an electric field is generated between the pair of electrodes, a magnetic field is generated around a processing space formed between the pair of electrodes, a plasma of a process gas is generated by an RF electric field generated in this state between the pair of electrodes, and the substrate to be processed has plasma processing applied to it.

According to the present invention, a magnetic field is generated around the processing space by the magnetic field generating means. The position where the substrate to be processed is present is set in a substantial non-magnetic field state, so as to prevent charge-up damage. A plasma confining effect can be exhibited by the magnetic field. Even when the RF power to be applied has a high frequency, the plasma processing rate of the substrate to be processed located in the processing space is made uniform.

A ring magnet in a multi-pole state formed by connecting around the chamber in a ring-like shape a plurality of segment magnets comprised of permanent magnets is used as the magnetic field generating means. The ring magnet is rotated in the circumferential direction of the chamber by the rotating mechanism. Thus, a phenomenon in which the chamber inner wall is locally chipped can be prevented.

A conductive or insulating focus ring is formed on the periphery of the substrate to be processed on the electrode. This can enhance the plasma process uniformity effect. More specifically, when a conductive focus ring is formed, a region up to the focus ring region serves as the electrode. Thus, the plasma generating region expands onto the focus ring. The plasma process at the periphery of the substrate to be processed is promoted, so the processing uniformity is improved. When an insulating focus ring is used, charge exchange cannot be performed between the focus ring and electrons or ions of the plasma. Hence, the operation of confining the plasma is enhanced, and the process uniformity effect is further improved.

The present invention is particularly effective when the frequency of the RF power is as high as 13.56 MHz to 150 MHz and the plasma process tends to be nonuniform. As the RF wave applying means, a first RF power supply for applying an RF wave for plasma generation and a second RF power supply for applying an RF wave for ion attraction can be used. In this case, the frequency of the first RF power supply can be set to 13.56 MHz to 150 MHz, and the frequency of the second RF power supply can be set to 500 kHz to 5 MHz.

### BRIEF DESCRIPTION OF THE SEVERAL VIEWS OF THE DRAWING

FIG. 1 is a view showing an arrangement of a plasma etching apparatus according to one embodiment of the present invention;

FIG. 2 is a view showing one arrangement of a ring magnet arranged around a chamber for the plasma etching apparatus shown in FIG. 1;

FIG. 3 is a view showing a conceptual arrangement of a portion of a plasma processing apparatus having an RF power supply for plasma generation and an RF power supply for ion attraction;

FIG. 4A is a graph showing through comparison the uniformity of the etching rate when etching is performed without using a magnet, and FIG. 4B is a graph showing through comparison the uniformity of the etching rate when etching is performed after a magnetic field is generated around the processing space by a multi-pole magnet in accordance with the present invention;

FIGS. 5A to 5G are views for explaining magnetic fields generated depending on the positions of segment magnets;

FIG. 6 is a graph showing the relationship between the field strength and the position in accordance with the layouts of the segment magnets shown in FIGS. 5A to 5G; and

FIG. 7 is a view showing an example of a conventional apparatus using a dipole ring magnet.

### DETAILED DESCRIPTION OF THE INVENTION

The embodiments of the present invention will be described with reference to the accompanying drawings.

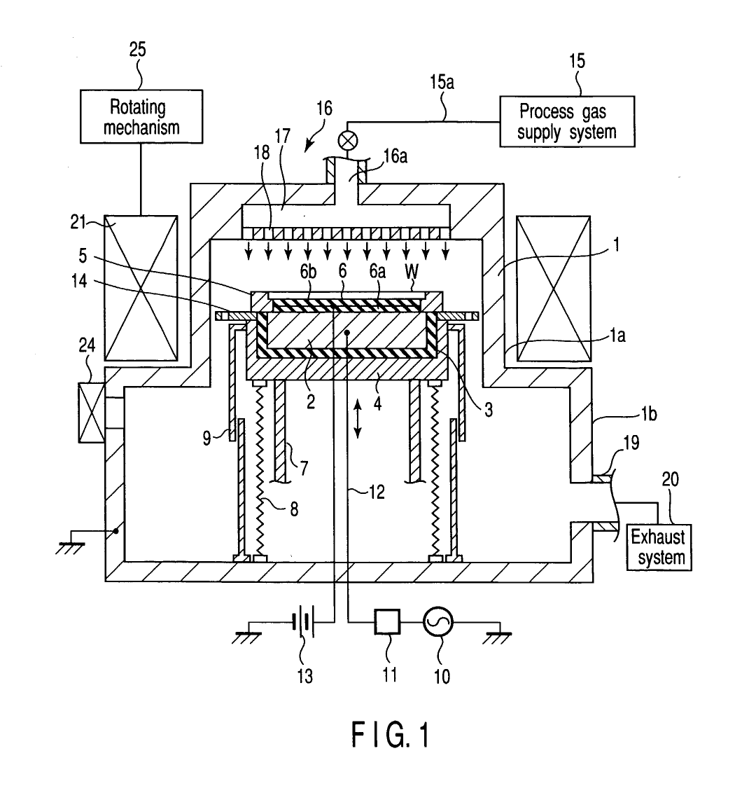

FIG. 1 is a sectional view showing an arrangement of a plasma etching apparatus according to an embodiment of the present invention.

This etching apparatus has a hermetic chamber 1. The chamber 1 forms a stepped cylindrical shape constituted by a small-diameter upper portion 1a and large-diameter lower portion 1b. The wall of the chamber 1 is made of, e.g., aluminum. A support table 2 (susceptor) for horizontally supporting thereon a semiconductor wafer (to be referred to as a wafer hereinafter) W as a substrate to be processed is arranged in the chamber 1. For example, the support table 2 is made of aluminum, and is supported on a conductive support base 4 through an insulating plate 3. A focus ring 5 made of a conductive material or insulating material is arranged on the periphery of the support table 2. As the focus ring, one with a diameter of 240 mm to 280 mm is employed when the wafer W has a diameter of 200 mm.

The support table 2 and support base 4 can be vertically moved by a ball screw mechanism including ball screws 7. A driving portion under the support base 4 is covered by a stainless steel (SUS) bellows 8. The chamber 1 is grounded. The support table 2 has a refrigerant flow channel (not shown) in it, so it can be cooled. A bellows cover 9 is arranged outside the bellows 8.

The support table 2 is connected to a feeder 12 at its substantial center, so RF power is supplied to it. The feeder 12 is connected to a matching box 11 and RF power supply 10. The RF power supply 10 supplies RF power within a range of 13.56 MHz to 150 MHz, preferably 13.56 MHz to 67.8 MHz, e.g., 40 MHz, to the support table 2. A shower head 16 (to be described later) is arranged above the support table 2 to oppose it such that they are parallel. The shower head 16 is grounded. Thus, the support table 2 and shower head 16 serve as a pair of electrodes.

An electrostatic chuck 6 for electrostatically attracting the wafer W is arranged on the surface of the support table 2. The electrostatic chuck 6 is constituted by insulators 6b and an electrode 6a interposed between them. The electrode 6a is connected to a DC power supply 13. The power supply 13 applies a voltage to the electrode 6a. Thus, the semiconductor wafer W can be attracted by, e.g., the Coulomb force. A refrigerant channel (not shown) is formed in the support table 2. When an appropriate refrigerant is circulated in the refrigerant channel, the wafer W can be controlled to a predetermined temperature. A gas inlet mechanism (not shown) is provided to supply He gas to the lower surface of the wafer W. Hence, cold heat from the refrigerant is transferred to the wafer W efficiently. A baffle plate 14 is formed outside the focus ring 5. The baffle plate 14 is electrically connected to the chamber 1 through the support base 4 and bellows 8.

The shower head 16 is formed on the ceiling of the chamber 1 to oppose the support table 2. The shower head 16 has a large number of gas discharge holes 18 in its lower surface, and a gas inlet portion 16a in its upper portion. A space 17 is formed in the shower head 16. The gas inlet portion 16a is connected to a gas supply pipe 15a. The other end of the gas supply pipe 15a is connected to a process gas supply system 15 for supplying a process gas. The process gas includes an etching reaction gas and diluent gas. As the reaction gas, a halogen-based gas can be used. As the diluent gas, a gas ordinarily used in this field, e.g., Ar gas, He gas, or the like, can be used.

The process gas is supplied from the process gas supply system 15 to reach the space 17 of the shower head 16 through the gas supply pipe 15a and gas inlet portion 16a. The process gas is then discharged from the gas discharge holes 18 to serve for etching of a film formed on the wafer W.

An exhaust port 19 is formed in the side wall of the lower portion 1b of the chamber 1, and is connected to an exhaust system 20. When a vacuum pump provided in the exhaust system 20 is actuated, the interior of the chamber 1 can be pressure-reduced to a predetermined vacuum degree. A gate valve 24 is formed in the upper side of the side wall of the lower portion 1b of the chamber 1. The gate valve 24 opens and closes a loading/unloading port for the wafer W.

A ring magnet 21 is concentrically arranged around the upper portion 1a of the chamber 1. The ring magnet 21 forms a magnetic field in the processing space between the support table 2 and shower head 16. The ring magnet 21 can be rotated by a rotating mechanism 25.

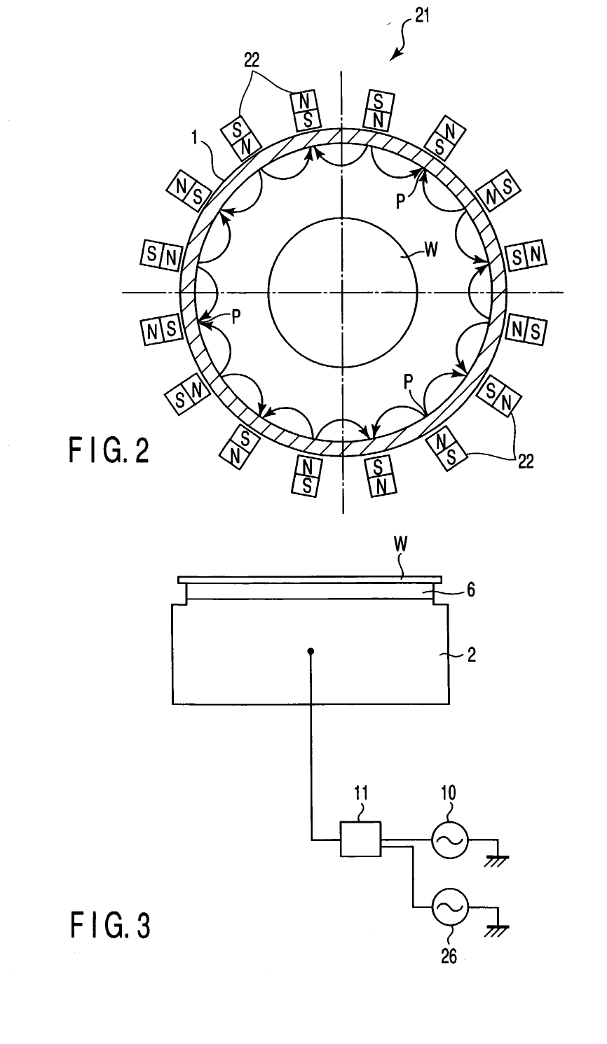

As shown in the horizontal sectional view of FIG. 2, the ring magnet 21 is formed of a plurality of segment magnets 22 formed of permanent magnets. The segments magnets 22 are arranged in a ring-like shape while they are supported by a support member (not shown). In this example, 16 segment magnets 22 are arranged in a multi-pole state to have a ring-like shape (concentrically). More specifically, in the ring magnet 21, the plurality of segment magnets 22 are arranged such that the adjacent segment magnets 22 have opposite magnetic poles. Consequently, the lines of magnetic force are formed between the adjacent segment magnets 22 as shown in FIG. 2. For example, a magnetic field of 200 Gauss to 2,000 Gauss (0.02 T to 0.2 T), preferably 300 Gauss to 450 Gauss, is formed at the periphery of the processing space, i.e., in the vicinity of the inner wall of the chamber. Accordingly, the center of the wafer is substantially set in a non-magnetic field state. The range of magnetic field strength is regulated in this manner due to the following reason. If the magnetic field is excessively strong, it causes a leaking magnetic field. If the magnetic field is excessively weak, the effect of plasma confinement cannot be obtained. These figures are merely examples in accordance with the structural (material) factor of the apparatus, and are not necessarily limited within these ranges.

When the periphery of the processing space is a magnetic field like this, the magnetic field above the focus ring 5 is preferably 10 Gauss or more. This is because E×B drift must be generated on the focus ring, thereby increasing the plasma density on the periphery of the wafer. In view of damage, the lower the magnetic field strength on the wafer edge portion, the better. When, however, the effect of the focus ring described above is expected, the magnetic field strength is preferably 10 Gauss or less.

The substantial non-magnetic field at the center of the wafer described above is originally preferably 0 Gauss. This suffices as far as a magnetic field that adversely affects the etching process is not formed at the portion where the wafer is arranged, so the wafer process is not substantially adversely affected.

In the state shown in FIG. 2, a magnetic field with a magnetic flux density of, e.g., 4.2 Gauss (420 μT) or less is applied to the periphery of the wafer. Hence, the function of confining the plasma is exhibited. The number of segment magnets is not limited to this. For example, the number of segment magnets in the circumferential direction of the chamber is preferably 16 or more, and preferably 32 or less in view of economy and manufacturing convenience. This is due to the following reason. Variations in magnetic field strength of the magnetic field forming region on the inner wall side of the chamber toward the chamber appear to be uniform because of the rotation of the ring magnet (to be described later). When local chipping of the wall portion of the actual chamber and instability of plasma confinement are considered, the variations in magnetic field strength are preferably suppressed to 10% or less.

The sectional shape of the anisotropic segment magnet is not limited to a rectangular one as in this example, but any other arbitrary shape can be employed, e.g., a circular, square, or trapezoidal shape. The magnetic material that forms the anisotropic segment magnets 22 is not limited particularly. A known magnetic material can be employed, e.g., a rare earth-type magnet, a ferrite-type magnet, or an Alnico magnet.

A process of the plasma etching apparatus having the above arrangement will be described.

First, the gate valve 24 is opened. The wafer W is loaded into the chamber 1 and placed on the support table 2 by a transfer mechanism (not shown). After the transfer mechanism is retreated to the outside of the chamber 1, the gate valve 24 is closed, and the support table 2 is moved upward to the position shown in FIG. 1. The vacuum pump of the exhaust system 20 evacuates the interior of the chamber 1 through the exhaust port 19.

After the interior of the chamber 1 reaches a predetermined vacuum degree, a predetermined process gas is introduced into the chamber 1 from the process gas supply system 15 at about, e.g., 100 sccm to 1,000 sccm (0.1 L/min to 1 L/min). The interior of the chamber 1 is thus held at a predetermined pressure, e.g., 10 mTorr to 1,000 mTorr (1.33 Pa to 133.3 Pa), preferably about 20 mTorr to 200 mTorr (2.67 Pa to 26.66 Pa). In this state, the RF power supply 10 supplies RF power to the support table 2. The RF power has a frequency of 13.56 MHz to 150 MHz, e.g., 40 MHz, and a power of 100 W to 3,000 W. At this time, the DC power supply 13 applies a predetermined voltage to the electrode 6a of the electrostatic chuck 6, and the wafer W is attracted by, e.g., the Coulomb force. In this case, the RF power is applied in the above manner to the support table 2 serving as a lower electrode. Thus, an RF electric field is formed in the processing space between the shower head 16 serving as the upper electrode and the support table 2 serving as the lower electrode. This plasmatizes the process gas supplied to the processing space. This plasma etches a predetermined film on the wafer W.

When high-frequency RF power is applied in order to increase the plasma density, the etching rate on the periphery of the wafer becomes relatively smaller than that at the center of the wafer. This phenomenon can be suppressed by forming a magnetic field around the wafer.

When this etching is to be performed, the ring magnet 21 in the multi-pole state forms the magnetic field as shown in FIG. 2 around the processing space. As this magnetic field is formed around the processing space, substantially no magnetic field is formed where the wafer W is present, and charge-up damage will not occur. With this magnetic field, the plasma confining effect is exhibited, and the etching rate at the edge of the wafer W can be increased. Even when the frequency of the RF wave to be applied is as high as 13.56 MHz to 150 MHz and preferably 13.56 MHz to 67.8 MHz, the etching rate of the wafer W can be substantially equalized between the edge and the center of the wafer W. Thus, the etching rate can be made uniform.

When a magnetic field is formed by such ring magnets in the multi-pole state, those portions of the wall of the chamber 1 which correspond to the magnetic poles (e.g., portions indicated by P in FIG. 2) may undesirably be locally chipped away. In contrast to this, the rotating mechanism 25 for rotating the ring magnet 21 at a desired rotational speed around the chamber 1 with a driving source such as a motor is provided. Since the ring magnet 21 is rotated in the circumferential direction of the chamber 1, the magnetic poles move relative to the chamber wall. As a result, the magnetic field does not concentrate at one portion, and local chipping of the chamber wall is prevented.

The conductive or insulating focus ring 5 is arranged on the periphery of the wafer W on the support table 2 serving as the lower electrode. This can further enhance the uniformity effect of the plasma processing. More specifically, when the focus ring 5 is made of a conductive material such as silicon or SiC, the focus ring region also serves as the lower electrode. Thus, the plasma forming region enlarges to cover a portion above the focus ring 5. The plasma process at the periphery of the wafer W is promoted, and the uniformity of the etching rate is improved. When the focus ring 5 is made of an insulating material such as quartz, charge exchange cannot be performed between the focus ring 5 and electrons and/or ions of the plasma. Thus, the plasma confinement operation can be enhanced, and the uniformity of the etching rate can be improved.

From the viewpoint of further increasing the etching rate, the RF wave for generating the plasma and the RF wave for attracting the ions in the plasma are preferably superposed. More specifically, as shown in FIG. 3, in addition to the RF power supply 10 for plasma generation, an RF power supply 26 for ion attraction is connected to the matching box 11, and the two RF waves are superposed. In this case, as the RF power supply 26 for ion attraction, one with a frequency within a range of 500 kHz to 13.56 MHz is used.

The relationship between the etching target film (e.g., a silicon oxide film, polysilicon film, or organic material film) formed on the wafer and the frequency to be supplied by the RF power supply will be described. In this relationship, figures without parentheses are preferable figures, and figures in parentheses are further preferable figures.

| Etching Target | Relatively High | Relatively Low |
|---|---|---|
| Film | Frequency | Frequency |
| | (RF for Plasma | (RF for Bias |
| | Generation) | Voltage Control) |
| Silicon Oxide | 13.56 MHz to 150 MHz | 500 kHz to 5 MHz |
| Film | (40 MHz to 100 MHz) | (3.2 MHz) |
| Polysilicon | 40 MHz to 150 MHz | 3.2 MHz to |
| Film | (40 MHz to 100 MHz) | 13.56 MHz |
| | (40 MHz to 100 MHz) | (13.56 MHz) |
| Organic | 40 MHz to 150 MHz | 3.2 MHz to |
| Material | (40 MHz to 100 MHz) | 13.56 MHz |
| Film | (40 MHz to 100 MHz) | (13.56 MHz) |

As the organic material film, an interlayer dielectric film on a silicon substrate can be taken as a typical example. The interlayer dielectric film is made of an organic material with a low dielectric constant, which has a specific dielectric constant much smaller than that of a conventional silicon oxide film. Examples of an organic material with a low dielectric constant include a polyorganosiloxane crosslinked bisbenzocyclobutene resin (BCB), SiLK (tradename) and FLARE (tradename) available from DowChemical. Organic polysiloxane refers to those compound which contain a functional group containing C and H in a bonding structure of a silicon oxide film, as in the structure below. In the structure below, reference symbol R denotes an alkyl group such as a methyl group, ethyl group, or propyl group, or its derivative, or an aryl group such as a phenyl group, or its derivative.

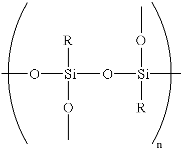

In the above relationship between the etching target film and the frequency of the RF power supply, RF power with a relatively RF of 40 MHz to 100 MHz for plasmatizing the etching gas, and RF power with a relatively low frequency of 3.2 MHz or 13.56 MHz for controlling the bias voltage that attracts the generated ions to the wafer are applied to the lower electrode. A magnetic field is generated around the wafer (the magnetic field above the wafer is 10 Gauss or less), thereby confining the plasma.

When etching of a silicon oxide film that requires a high bias voltage is to be performed, the RF power with a relatively low frequency preferably has a frequency of 3.2 MHz. When etching of a polysilicon film (or silicon substrate) or organic material film that requires a low bias voltage is to be performed, the RF power with a relatively low frequency preferably has a frequency of 13.56 MHz.

Comparison results of a case wherein etching is performed without using a magnet and a case wherein etching is performed after a magnetic field is generated around the processing space by a multi-pole magnet according to the present invention will be described.

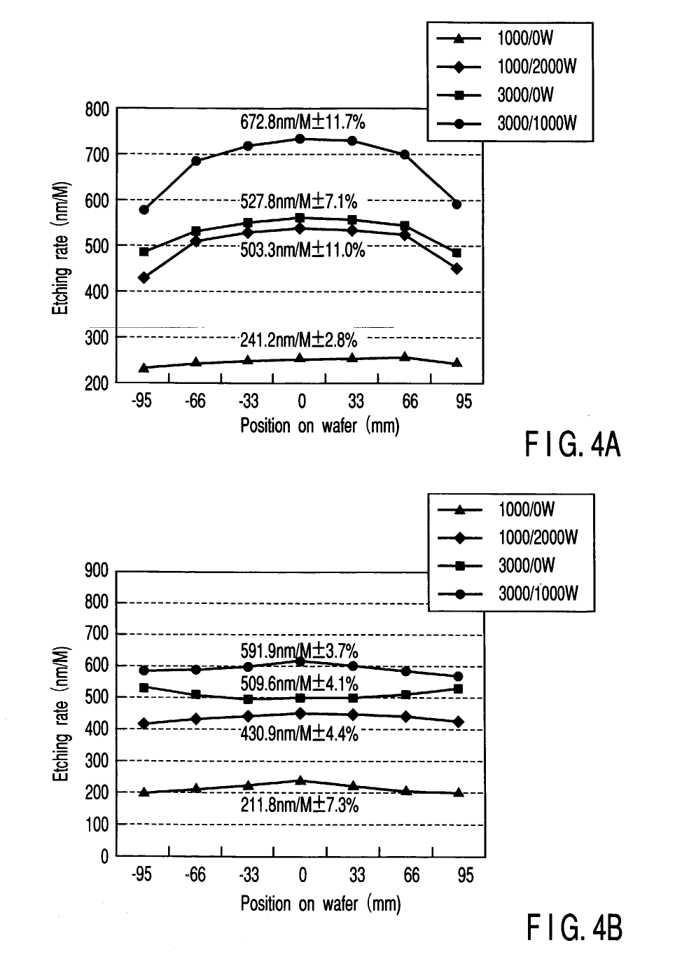

As the RF power supply for plasma generation, one with a frequency of 40 MHz was used. As the RF power supply for ion attraction, one with a frequency of 3.2 MHz was used. As the process gas, C₄H₈, O₂, and Ar were introduced into the chamber with a flow rate ratio of 2:1:10 and with a total flow rate of 130 sccm (0.13 L/min) to set the pressure in the chamber to 50 mTorr (6.67 Pa). The etching process was performed while changing the powers supplied from the RF power supplies. FIG. 4 shows the results.

As shown in FIG. 4A, when the magnet was not used, the etching rate was high at the wafer center but low at the periphery, leading to poor etching rate uniformity. As shown in FIG. 4B, when a magnetic field was formed around the processing space by using a multi-pole magnet in accordance with the present invention, the etching rate uniformity improved greatly under any conditions.

Plasma confinement performed for improving the etching rate uniformity changes depending on the target etching material and etching gas. Assume that a silicon oxide film is to be etched with, e.g., a gas mixture containing a fluorocarbon-based gas. In this case, the difference in etching rate between the wafer periphery and wafer center is larger than that in a case wherein an organic insulating film is to be etched with a gas mixture containing N₂ and H₂ (etching rate at wafer center>etching rate at wafer periphery).

For example, when a silicon oxide film is to be etched, the plasma must be confined sufficiently. When an organic insulating film is to be etched, the plasma must be confined moderately. In this manner, the plasma confined state must be controllable.

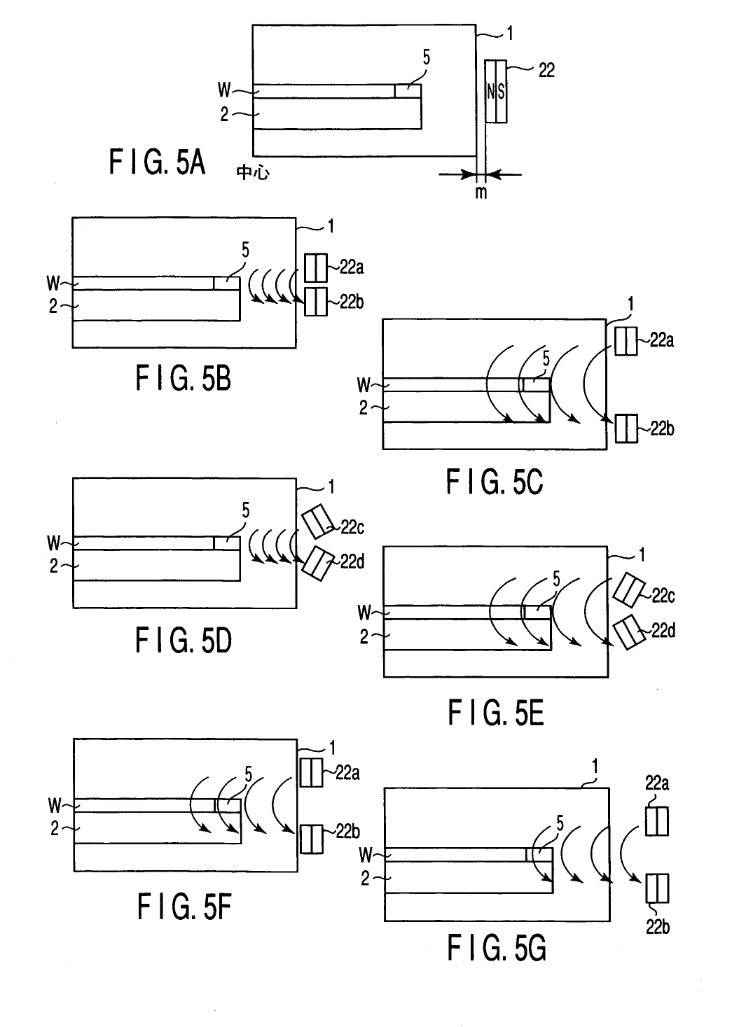

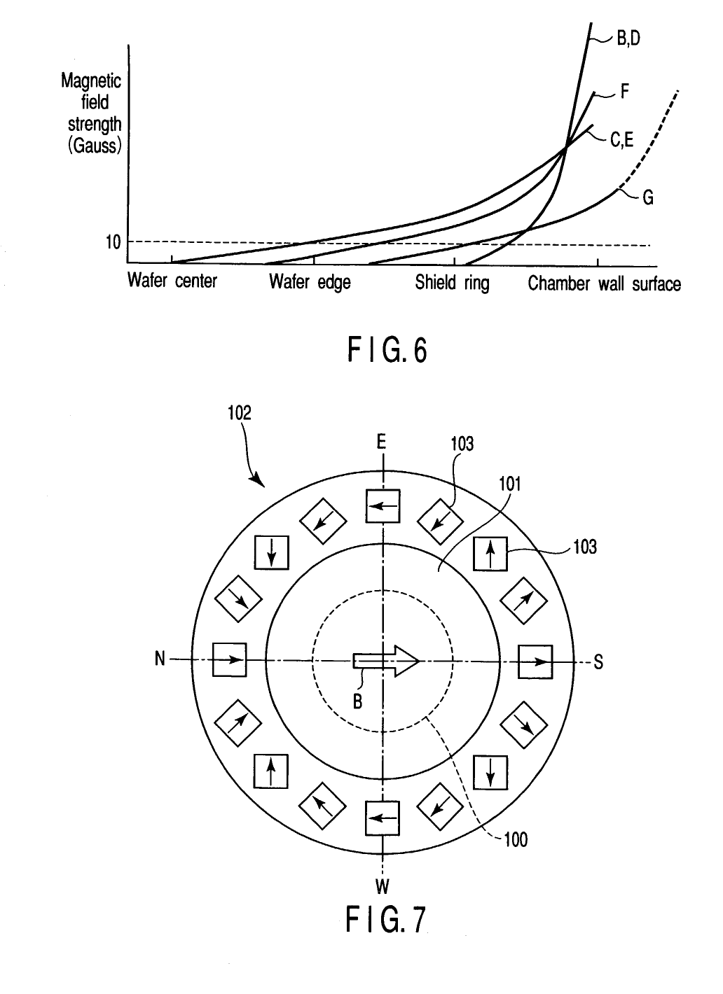

FIGS. 5A to 5G show and explain magnetic fields generated depending on the arrangement, direction, and the like of the segment magnets. FIG. 6 is a graph showing the relationship between the magnetic field strength and position in accordance with the arrangement of the segment magnets shown in FIGS. 5A to 5G.

FIG. 5A shows a standard arrangement applied to the embodiment described above. The segment magnets are arranged away from the side wall of the chamber 1 by a predetermined distance m. With this arrangement, changing the magnetic field generating state (the magnetic field profile to the magnetic field of the inner wall of the chamber) is realized by changing the magnetic forces of the segment magnets or the lengths of the magnets in the vertical direction.

In FIG. 5B, the ring-like segment magnets 22 are vertically halved into ring magnets 22a and 22b, and these magnets are arranged with a slight vertical distance (gap) between them. In FIG. 5C, the magnets are arranged with a larger distance between them than in FIG. 5B. In these examples, the magnetic field is generated such that the smaller the gap between the magnets, the smaller the arcs of the lines of magnetic force, and the larger the distance between the magnets, the larger the arcs of the lines of magnetic force. The directions of magnetization of the upper and lower ring magnets may all be the same. If adjacent ones of the segment magnets arranged in a ring-like shape are directed in opposite directions, portions with the same magnetic pole (portions P of FIG. 2) are dispersed. This is preferable because chipping of the inner wall of the chamber 1 is suppressed. The apparatus also has a vertical moving mechanism and rotating mechanism. The vertical moving mechanism moves the ring magnets 22a and 22b vertically. The rotating mechanism rotates the ring magnets 22a and 22b in the circumferential direction of the chamber 1 at a desired rotational speed.

In FIGS. 5D and 5E, the ring-like segment magnets 22 are vertically halved into ring magnets 22c and 22d, and are further multi-divided in the direction of the ring. The multi-divided magnets are connected annularly and arranged to be pivotal. In FIG. 5D, the ring magnets 22c and 22d are pivoted such that the angle of their directions of magnetization is 180° or less. This forms the following magnetic field. As the ring magnets are pivoted in these directions, the arcs of the lines of magnetic force become small. Conversely, in FIG. 5E, the following magnetic field is formed. When the ring magnets 22c and 22d are pivoted such that the angle of their directions of magnetization becomes 180° or more, the arcs of the lines of magnetic force become large.

In this arrangement as well, the apparatus has the same rotating mechanism as that described above, and a pivoting mechanism for pivoting the ring magnets 22c and 22d such that the directions (angle) of their lines of magnetic force change. In FIG. 5F, halved ring magnets 22a and 22b are moved to be closer than the distance m shown in FIG. 5A, that is, the ring diameter is decreased. In this case, a magnetic field with strong lines of magnetic force is generated. Conversely, in FIG. 5G, ring magnets 22a and 22b are moved to be farther than the distance m, that is, the ring diameter is increased. In this case, a magnetic field with weak lines of magnetic force is generated. A diameter alteration mechanism which changes the diameters of the ring magnets in this manner may be provided. Then, a necessary plasma confined state can be arbitrarily formed.

The present invention is not limited to the above embodiment, but can be changed in various manners. For example, in the above embodiment, as the magnetic field generating means, a ring magnet in a multi-pole state obtained by arranging a plurality of segment magnets, comprised of permanent magnets, around the chamber in a ring-like shape is used. However, the present invention is not limited to this as far as a magnetic field is generated around the processing space so that the plasma can be confined.

In the above embodiment, a semiconductor wafer is used as the substrate to be processed, but the present invention is not limited to this. In the above embodiment, the present invention is applied to a plasma etching apparatus. However, the present invention is not limited to this, but can also be applied to any other plasma process. More specifically, the present invention can be applied to a plasma CVD apparatus in which the process gas is changed from an etching gas to a known CVD gas. The present invention can also be applied to a plasma sputtering apparatus in which a target is arranged in a chamber to oppose an object to be processed.

As has been described above, according to the present embodiment and present invention, a magnetic field is generated around a processing space by a magnetic field generating means. Thus, while the position where a substrate to be processed is present is set in a substantial non-magnetic field state to prevent charge-up damage, the plasma confining effect can be exhibited by this magnetic field. Even when the RF power to be applied has a RF, the plasma processing rate, e.g., the etching rate, of the substrate to be processed located in the processing space can be set almost equal between the edge and center of the substrate to be processed. As a result, the processing rate can be made uniform.

In order to generate a magnetic field around such a processing space, a ring magnet in a multi-pole state formed by arranging a plurality of segment magnets, comprised of permanent magnets, around the chamber in a ring-like shape may be used. When a magnetic field is generated by such a ring magnet in the multi-pole state, the chamber wall may be chipped away at its portions corresponding to the magnetic poles. In contrast to this, when a rotating means for rotating the ring magnet in the circumferential direction of the chamber is provided, the above inconvenience can be eliminated.

As the magnetic field generating means, the present invention uses segment magnets comprised of permanent magnets. Thus, a power supply circuit or power supply for generating the magnetic field becomes unnecessary. The apparatus arrangement becomes simple, so the cost can be suppressed. In this arrangement, the segment magnets are not electrically connected, so they can be rotated or moved easily.

A conductive or insulating focus ring is formed around the substrate to be processed on the electrode. When a conductive focus ring is formed, the plasma process at the periphery of the substrate to be processed is promoted. When an insulating focus ring is formed, the operation of confining the plasma is enhanced. As a result, the plasma process uniformity effect can be further enhanced.

The present invention is a technique to be utilized by a plasma processing apparatus and plasma processing method that prevent charge-up damage and make uniform the processing rate when a substrate to be processed has plasma processing applied to it.

According to this plasma processing apparatus, ring-like segment magnets are arranged around the upper portion of the plasma in order to generate a magnetic field around the processing space. The segment magnets can be rotated by a rotating mechanism in the circumferential direction of the chamber. A magnetic field is generated around the processing space by a magnetic field generating means. The position where the substrate to be processed is present is set in a substantial non-magnetic field state. Charge-up damage is thus prevented. Because of the plasma confining effect of this magnetic field, the plasma processing rate of the substrate to be processed is set to be substantially equal between the edge and center of the substrate to be processed. As a result, the processing rate is made uniform.

What is claimed is:

1. A plasma processing apparatus comprising
a chamber capable of maintaining a vacuum state,
first and second electrodes formed in the chamber to oppose each other,
RF power applying means for applying a RF power to the second electrode to generate an electric field between the first and second electrodes,
process gas supply means for supplying a process gas into the chamber,
magnetic field generating means, provided around the chamber, for generating, at the periphery of a processing space formed between the first and second electrodes, a magnetic field stronger than a magnetic field at the center of the processing space, and
rotating means for rotating the magnetic field generating means in a circumferential direction of the chamber,
wherein while a magnetic field is generated around the processing space by the magnetic field generating means, a plasma of the process gas is generated by a high-frequency electric field generated between the first and second electrodes so a substrate to be processed has plasma processing applied to it.

2. A plasma processing apparatus comprising
a chamber capable of maintaining a vacuum state,
first and second electrodes formed in the chamber to oppose each other,
RF power applying means for applying a RF power to the second electrode to generate an electric field between the first and second electrodes,
process gas supply means for supplying a process gas into the chamber,
magnetic field generating means, provided around the chamber, for generating, at the periphery of a processing space formed between the first and second electrodes, a magnetic field stronger than a magnetic field at the center of the processing space, and
rotating means for rotating the magnetic field generating means in a circumferential direction of the chamber,
wherein while a magnetic field is generated around the processing space by the magnetic field generating means, a plasma of the process gas is generated by a high-frequency electric field generated between the first and second electrodes, and when a polysilicon film is to be etched, a RF power for plasma generation generated by a first RF power supply has a frequency of 40 MHz to 150 MHz, and a second RF power supply has a frequency of 3.2 MHz to 13.56 MHz.

3. A plasma processing apparatus comprising
a chamber capable of maintaining a vacuum state,
first and second electrodes formed in the chamber to oppose each other,
RF power applying means for applying a RF power to the second electrode to generate an electric field between the first and second electrodes,
process gas supply means for supplying a process gas into the chamber,
magnetic field generating means, provided around the chamber, for generating, at the periphery of a processing space formed between the first and second electrodes, a magnetic field stronger than a magnetic field at the center of the processing space, and
rotating means for rotating the magnetic field generating means in a circumferential direction of the chamber,
wherein while a magnetic field is generated around the processing space by the magnetic field generating means, a plasma of the process gas is generated by a high-frequency electric field generated between the first and second electrodes, and when an organic material film is to be etched, a RF power for plasma generation generated by a first RF power supply has a frequency of 40 MHz to 150 MHz, and a second RF power supply has a frequency of 3.2 MHz to 13.56 MHz.

4. A plasma processing apparatus according to claim 1, wherein the magnetic field generating means has a ring magnet in a multi-pole state formed by arranging a plurality of segment magnets comprised of permanent magnets around the chamber in a ring-like shape.

5. A plasma processing apparatus comprising
a chamber capable of maintaining a vacuum state,
first and second electrodes formed in the chamber to oppose each other,
RF power applying means for applying a RF power to the second electrode to generate an electric field between the first and second electrodes,
process gas supply means for supplying a process gas into the chamber,
magnetic field generating means, having first and second ring magnets in a multi-pole state each formed by arranging around the chamber in a ring-like shape a plurality of segment magnets comprised of permanent magnets arranged in opposing directions between the first and second electrodes, the magnets being arranged with arbitrary gaps therebetween, for generating, at the periphery of a processing space formed between the first and second electrodes, a magnetic field stronger than a magnetic field at the center of the processing space,
rotating means for rotating the magnetic field generating means in a circumferential direction of the chamber, and
a moving mechanism which changes a gap between the first and second ring magnets of the magnetic field generating means,
wherein the gap is changed by moving at least one of the first and second ring magnets.

6. A plasma processing apparatus comprising
a chamber capable of maintaining a vacuum state,
first and second electrodes formed in the chamber to oppose each other,
RF power applying means for applying a RF power to the second electrode to generate an electric field between the first and second electrodes,
process gas supply means for supplying a process gas into the chamber,
magnetic field generating means, having first and second ring magnets in a multi-pole state each formed by arranging around the chamber in a ring-like shape a plurality of segment magnets comprised of permanent magnets arranged in opposing directions between the first and second electrodes, the magnets being arranged with arbitrary gaps therebetween, for generating, at the periphery of a processing space formed between the first and second electrodes, a magnetic field stronger than a magnetic field at the center of the processing space,
rotating means for rotating the magnetic field generating means in a circumferential direction of the chamber, and
a pivotal mechanism which pivots the first and second ring magnets of the magnetic field generating means so as to change the directions of the lines of magnetic force (directions of magnetization) between the first and second ring magnets,
wherein the direction of the lines of magnetic force of at least one of the first and second ring magnets is changed.

7. A plasma processing apparatus comprising
a chamber capable of maintaining a vacuum state,
first and second electrodes formed in the chamber to oppose each other,
RF power applying means for applying a RF power to the second electrode to generate an electric field between the first and second electrodes,
process gas supply means for supplying a process gas into the chamber,
magnetic field generating means, having first and second ring magnets in a multi-pole state each formed by arranging around the chamber in a ring-like shape a plurality of segment magnets comprised of permanent magnets arranged in opposing directions between the first and second electrodes, the magnets being arranged with arbitrary gaps therebetween, for generating, at the periphery of a processing space formed between the first and second electrodes, a magnetic field stronger than a magnetic field at the center of the processing space,
rotating means for rotating the magnetic field generating means in a circumferential direction of the chamber, and
a diameter changing mechanism which changes the diameters of the first and second ring magnets of the magnetic field generating means to change the strengths of the lines of magnetic force thereof,
wherein the diameter of at least one of the first and second ring magnets is changed.

8. A plasma processing apparatus comprising
a chamber capable of maintaining a vacuum state,
first and second electrodes formed in the chamber to oppose each other,
RF power applying means for applying a RF power to the second electrode to generate an electric field between the first and second electrodes,
process gas supply means for supplying a process gas into the chamber,
magnetic field generating means, having first and second ring magnets in a multi-pole state each formed by arranging around the chamber in a ring-like shape a plurality of segment magnets comprised of permanent magnets arranged in opposing directions between the first and second electrodes, the magnets being arranged with arbitrary gaps therebetween, for generating, at the periphery of a processing space formed between the first and second electrodes, a magnetic field stronger than a magnetic field at the center of the processing space, and
rotating means for rotating the magnetic field generating means in a circumferential direction of the chamber,
wherein the magnetic poles of the opposing segment magnets of the first and second ring magnets are in opposite directions.

9. A plasma processing apparatus comprising
a chamber capable of maintaining a vacuum state,
plasma processing means for introducing a process gas into the chamber so as to generate a plasma, thereby processing an object to be processed with the plasma,
magnetic field generating means, provided around the chamber, for generating a magnetic field which does not require power supply, is formed of fixed magnetic forces, and acts to confine the plasma from the periphery side of the object to be processed, and
moving and rotating means for moving the magnetic field generating means away from or close to around the processing space and for rotating the magnetic field generating means around the chamber,
wherein the magnetic force of a magnetic field to be supplied to the periphery of the processing space is changed by driving the moving and rotating means.

10. A plasma processing apparatus according to claim 4, further comprising a conductive or insulating focus ring formed around the substrate to be processed on the second electrode.

11. A plasma processing apparatus according to claim 4, wherein the RF power applying means applies RF power with a frequency of 13.56 MHz to 150 MHz.

12. A plasma processing apparatus according to claim 4, wherein the RF power applying means has
a first RF power supply for applying a RF power for plasma generation, and
a second RF power supply for applying a RF power for ion attraction.

13. A plasma processing apparatus according to claim 4, wherein the first RF power supply has a frequency of 13.56 MHz to 150 MHz, and the second RF power supply has a frequency of 500 kHz to 5 MHz.

14. A plasma processing apparatus according to claim 4, wherein when the plasma processing apparatus is to etch a silicon oxide film, a RF power for plasma generation generated by the first RF power supply has a frequency of 13.56 MHz to 150 MHz, and the second RF power supply has a frequency of 500 kHz to 5 MHz.

15. A plasma processing method of processing, with a plasma, a substrate to be processed loaded in a chamber capable of maintaining a vacuum state, comprising
a RF power applying step of applying a RF power to a second electrode which is formed in the chamber to oppose a first electrode, and generating an electric field between the first and second electrodes,
a process gas supply step of supplying a process gas into the chamber,
a magnetic field generating step of generating, at the periphery of a processing space, a magnetic field stronger than a magnetic field at the center of the processing space in the chamber, and
a rotating step of rotating the magnetic field generated at the periphery of the processing space in a direction crossing a surface at which the first and second electrodes oppose each other.
